(19) United States
(12) Patent Application Publication
(10) Pub. No.: US 2014/0021472 A1
(43) Pub. Date: Jan. 23, 2014

(54) PRINTABLE MEDIUM THAT CONTAINS METAL PARTICLES AND EFFECTS ETCHING, MORE PARTICULARLY FOR MAKING CONTACT WITH SILICON DURING THE PRODUCTION OF A SOLAR CELL

(71) Applicants: Giso Hahn, Konstanz (DE); Bernd Raabe, Konstanz (DE); Stefan Braun, Konstanz (DE)

(72) Inventors: Giso Hahn, Konstanz (DE); Bernd Raabe, Konstanz (DE); Stefan Braun, Konstanz (DE)

(73) Assignee: UNIVERSITÄT KONSTANZ, Konstanz (DE)

(21) Appl. No.: 14/110,065

(22) PCT Filed: Apr. 5, 2012
(86) PCT No.: PCT/EP2012/001608

§ 371 Date: Oct. 4, 2013

(30) Foreign Application Priority Data
Apr. 7, 2011 (DE) 10 2011 016 335.2

(51) Int. Cl. H01L 33/48; H01L 33/00

(52) U.S. Cl. CPC H01L 33/48; H01L 33/0058
USPC 257/53; 438/96

(57) ABSTRACT

A printable medium is proposed, such as can be used, for example, during the production of metal contacts for silicon solar cells which are covered with a passivation layer on a surface of a silicon substrate. A corresponding production method and a correspondingly produced solar cell are also disclosed. The printable medium contains at least one medium that etches the passivation layer and metal particles such as nickel particles, for example. By locally applying the printable medium to the passivation layer and subsequent heating, the passivation layer can be opened locally with the aid of the etching medium. As a result, the nickel particles can form a mechanical and electrical contact with the substrate surface, preferably with the formation of a nickel silicide layer. The printable medium and the production method made possible therewith are cost-effective owing to the use of nickel particles, for example, and allow both good electrical contact and avoidance of undesirable high-temperature steps.

### FIELD OF THE INVENTION

The present invention relates to a printable medium which may be used in particular for forming metal contacts on silicon solar cells. The invention furthermore relates to a method for production of silicon solar cells and a solar cell which may be produced accordingly.

### BACKGROUND TO THE INVENTION

A large proportion of solar cells currently manufactured industrially is produced on the basis of silicon substrates, wherein metal contacts on the surfaces of the silicon substrate are usually formed by printing processes such as for example screen-printing. Conventionally, metal contacts, in particular on the front of a silicon substrate, are formed using a printable paste which contains amongst others silver particles, glass frit and inorganic solvents, and which is printed onto the substrate surface in the form of a grid with narrow oblong contact fingers. After the paste has dried, it is typically driven into the substrate surface in a so-called firing step at temperatures above 700 to 800° C. If, before application of the printable paste onto the substrate surface, a dielectric layer was deposited for example as an antireflection layer and/or a passivation layer, the glass frit contained in the paste can serve to open the dielectric layer locally so that the silver particles, also contained in the paste, can form an electrically conductive contact with the underlying silicon, in particular with an emitter formed on the front surface of the substrate.

Conventional printable pastes used to form front contacts on solar cells, because of the silver particles contained therein and the high price of silver, make a substantial contribution to the overall costs in the production of solar cells. Furthermore the high temperatures, required during a firing step to open an underlying dielectric layer by means of the glass frit contained in conventional pastes, lead firstly to the need for substantial energy for the firing step and secondly, in specific solar cell designs, carry a risk of damage of the solar cells.

### SUMMARY OF THE INVENTION

There is therefore a need for an alternative, low-cost printable medium and a correspondingly low-cost method for production of solar cells, and solar cells which can be produced accordingly.

Such a demand may be satisfied with the invention according to the independent claims. Advantageous embodiments of the invention are defined in the dependent claims.

According to a first aspect of the present invention, a printable medium is proposed, in particular in the form of a printable paste, which is suitable both for opening by etching of a passivation layer and for making electrically conductive contact with a silicon substrate adjacent to the passivation layer. Therein, the passivation layer may comprise one or more dielectrics and/or amorphous silicon. The printable medium contains both a medium for chemically etching the passivation layer and metal particles, in particular nickel particles and/or titanium particles. The printable medium is substantially free from glass frit.

In other words, the first aspect of the invention concerns a printable medium which, because of its viscous properties, can be applied to a substrate using various printing methods. Suitable printing methods here include for example screen-printing, inkjet printing, inkpad printing, roller printing, laser transfer printing etc. Using the printable medium proposed here, further advantages can be achieved in addition to the known advantages of print-based deposition methods.

Printing processes, such as in particular screen-printing, are preferred in the formation of metal contacts in the industrial manufacture of solar cells in particular because of the possibility of simple process management and low costs in comparison with other metallisation technologies. For example using screen-printing processes, with comparatively simple mechanical means, structures with a structure width of less than 100 μm can be printed on a substrate. The definition of the structures is very largely freely definable by the type of printing mask used and the regions covered on this mask.

However disadvantages are also known in conventional screen printing metallisation processes for solar cells, which can be at least partially overcome using the printable medium proposed here.

For example for the formation of front contact fingers for solar cells, previously a printable paste was used which contained silver particles and glass frit. The silver particles in sintered state should provide the electrical conductivity of the structures applied by the screen-printing. The glass frit should serve to “eat through” a dielectric layer lying between the silicon substrate and the printed paste, in order to enable a mechanical and electrical contact between the surface of the silicon substrate and the silver particles.

As well as the cost problems mentioned above, because of the use of costly silver particles, when such conventional printable pastes are used it has also been observed that it is generally necessary to fire the paste into the silicon substrate through the dielectric layer at very high temperatures of over 700 to 800° C., in order to be able to create a satisfactory electrical contact with the silicon substrate. In addition to the energy supply to be provided for this, it has been found to be disadvantageous that, inter alia, passivating properties of the dielectric layer can be negatively influenced by the firing of the printable paste at very high temperatures.

It has also been observed that a contact resistance between the silver particles of the printable paste and the silicon of the substrate may be relatively high and make a significant contribution to the total series resistance by the metal contacts.

By the use of other metal particles proposed here, such as in particular nickel particles, instead of silver particles, the costs for a metal contact structure for a solar cell which can be produced with the printable paste can be significantly reduced. It has however been found that to achieve satisfactory results in the formation of contact structures, it is not sufficient simply to replace the silver particles in conventional printable pastes with nickel particles for example. In general only contact structures which suffer from other disadvantages, e.g. a substantial series resistance, may be produced with such slightly modified printable pastes.

It was however found surprisingly that by the addition of a medium for chemically etching a passivation layer, a substantially improved series resistance can be achieved for the contact structure produced. The medium etching the passivation layer may be a chemical adapted to the material of the passivation layer which may chemically attack and dissolve the passivation layer. As a result it may be achieved that after dissolution of the passivation layer, the nickel particles also contained in the printable paste may come into direct mechanical contact with a surface of the silicon substrate lying under the passivation layer. In particular at higher temperatures of for example between 350 and 550° C., nickel silicides may form at the contact points. It has been observed that in particular the formation of such a nickel silicide layer between the silicon substrate and the nickel particles of the contact structure appears to lead to a very low contact resistance between the nickel particles and the silicon surface. This contact resistance may be lower by a factor of 10 than that between silicon and silver.

Both the local opening of the passivation layer achieved by the etching medium and the formation of nickel silicide may take place at process temperatures which are substantially lower than the 700 to 800° C. used in conventional screen-printing metallisation processes. In particular process temperatures in the range from 200 to 600° may be sufficient to create metal contact structures with low contact resistance using the printable medium proposed here. Since the use of high process temperatures may therefore be omitted, any associated degradation for example of the properties of the passivation layer may be avoided.

To summarise, the printable medium proposed here may offer, as well as a cost reduction potential, a contact resistance which is reduced in comparison with screen-printing processes using conventional printable pastes and the possibility of lower process temperatures and associated therewith a reduced risk of degradation.

Further possible features and benefits of the printable medium proposed here are described below, partially in reference to embodiments of the invention. The embodiments are described in relation to a printable paste, wherein the features and properties described apply generally to arbitrary printable media, i.e. for example to higher viscosity pastes as used e.g. in screen-printing, and to low viscosity fluids as used for example in inkjet printing.

The printable paste may contain between 5 w. % and 90 w. %, preferably between 10 w. % and 80 w. %, and more preferably between 20 w. % and 70 w. % of the medium for etching the passivation layer. Such weight proportions of the etching medium in the total printable paste have proved advantageous for the etching properties of the printing paste. If the proportion of etching medium is too small, problems may occur in local opening of the passivation layer. Too high a proportion of etching medium may prevent a sufficiently high weight proportion of metal particles.

The paste contains between 5 w. % and 90 w. %, preferably between 10 w. % and 80 w. %, and more preferably between 20 w. % and 70 w. % metal particles. Too low a weight proportion may lead to excessively high series resistances in the metal contact structure produced. Too high a weight proportion of metal particles may prevent a sufficiently high weight proportion of etching medium.

The metal particles may have sizes between 20 nm and 50 μm, preferably between 50 nm and 20 μm. If the particles are too small, excessive oxidation or a defective electrical contact may occur. If the particles are too large, problems may occur in processing during printing. The nickel particles may here consist completely of nickel or comprise a nickel compound or nickel alloy. The same applies to alternative particles of titanium.

The printable paste proposed here is substantially free from glass frit. Glass frit may here mean small particles of low-melting glass, as frequently used in conventional printable pastes to form metal contact structures in order to “eat through” a dielectric passivation layer. In particular glass frit may contain metal oxides. It has been observed that metal oxides of such glass frit, in cooperation with the nickel particles contained for example in the proposed printing paste, may lead to the formation of nickel oxide which may reduce the electrical conductivity of the metal structures produced. It has also been observed that the high process temperatures necessary to melt the glass frit, or the melted glass frit itself, may lead to the nickel penetrating too deeply into the surface of the silicon substrate and, in particular if thin emitter layers are to be contacted, may lead to short-circuit problems. The omission of glass frit, and in particular glass frit which melts at high process temperatures of for example over 500° C., may thus help avoid short-circuit problems.

The passivation layer, on which the printable paste is to be applied and which is to be opened locally using the etching medium, may comprise a dielectric or a stack succession of multiple dielectric layers consisting for example of different forms of silicon nitride (Si₃N₄, SiNₓ:H, SiNₓO_{y}), silicon oxide (SiO, SiO₂), silicon carbide (SiCₓ) or aluminium oxide (Al₂O₃) and/or amorphous silicon (a-Si). The layer may here be formed with structural and electrical properties such as to achieve a good passivation of the adjacent surface of the silicon substrate with a low surface recombination velocity. For example using the passivation layer, surface recombination velocities of less than 1000 cm/s at an emitter surface and less than 100 cm/s at a base surface may be achieved. The passivation layer may here have a thickness of between 0.5 and 500 nm, preferably between 1 and 100 nm. The passivation layer need not necessarily however cause a very good surface passivation. Alternatively the passivation may be formed e.g. as a dielectric antireflection layer or as a dielectric back reflector for a solar cell in which a passivation effect may play a subordinate role. In industrial production methods, passivation layers are often formed with silicon nitride, for example Si₃N₄ or SiNₓ:H. Such silicon nitride layers may be deposited for example by gas phase deposition (CVD—Chemical Vapour Deposition) and cause very good surface passivation. Alternatively passivation layers may also be formed with silicon oxide, for example SiO₂, which may be generated for example by thermal oxidation or gas phase deposition. Recently aluminium oxide, for example Al₂O₃, has been found suitable for producing very high quality passivation layers. A good surface passivation may also be achieved with a very thin layer of amorphous silicon (a-Si) which may be provided intrinsically or doped.

Depending on which passivation layer is applied to a silicon substrate and is to be opened locally and contacted electrically conductively using the printable paste proposed here, other etching media may be included in the paste. The etching medium may in particular be adapted to dissolve the passivation layer chemically completely in a region which is to be covered with the printable medium. In other words, the material of the passivation layer may form a solution with the etching medium, in particular at high process temperatures, and thus be removed completely locally. In contrast, conventional screen-printing pastes, because of the glass frit contained therein, may indeed penetrate a passivation layer locally in the form of small so-called spikes but not dissolve this over wide areas.

For example the etching medium may contain one or more forms of phosphoric acid, phosphoric acid salts and/or phosphoric acid compounds. The phosphoric acid salts or phosphoric acid compounds may decompose on heating into a corresponding phosphoric acid which may then open the adjacent passivation layer by etching.

Depending on the passivation layer to be etched, the etching medium may also contain inorganic mineral acids such as for example hydrochloric acid, sulphuric acid or nitric acid. Organic acids which for example have an alkyl residue of 1 to 10 carbon atoms selected from the group of alkylcarbonic acids, hydroxycarbonic acids and dicarbonic acids, may be contained in the etching medium. Examples of these are formic acid, acetic acid, lactic acid and oxalic acid. Alternatively the etching medium may comprise etching alkaline compounds which may contain for example potassium hydroxide (KOH) or sodium hydroxide (NaOH) and in particular may etch thin amorphous silicon layers.

As well as said components, the proposed printable paste may contain further components such as for example solvents, thickeners, further inorganic or organic acids or alkaline compounds, adhesion promotion agents, de-aerators, anti-foaming agents, thixotropic agents, levelling agents etc. and/or particles of polymers and/or inorganic compounds.

According to a second aspect of the present invention, a method is proposed for production of a solar cell. The method comprises at least the following steps: provision of a silicon substrate; deposition of a passivation layer with a dielectric and/or amorphous silicon on a surface of silicon substrate; application of a printable medium to the passivation layer, wherein the printable medium contains at least a medium for chemically etching the passivation layer and metal particles and is substantially free from glass frit.

The printable paste applied during the production process may be a paste as has been described above in relation to the first aspect of the invention. The passivation layer to be deposited may also have properties as have already been described above.

By application of the special printable paste, both local opening of the passivation layer previously deposited and the formation of a local electrical contact between the nickel particles contained in the paste and the surface of silicon substrate may be achieved simultaneously.

Both processes, i.e. the etching of the silicon substrate surface and the contact formation, may take place at low process temperatures. For example it may suffice to heat the paste, or the silicon substrate with the paste thereon, to a temperature of between 200° C. and 600° C., preferably between 300° C. and 550° C., and greatly preferably between 350° C. and 500° C. Such heating firstly accelerates the etching effect of the etching medium and secondly may lead to the formation of a nickel silicide between the nickel particles and the silicon surface and to sintering of the nickel particles. The reliable production of metal contact structures with low electrical resistances may be achieved for example by heating to over 200° C., preferably over 350° C. for a duration between 5 s and 60 min, preferably with between 20 s and 10 min.

To reduce the electrical series resistance of the nickel contact structure formed by the applied printable paste, the structure may optionally be thickened by the application of an additional electrically conductive layer, e.g. by galvanic plating, currentless plating or light-induced plating. In the case of galvanic or light-induced plating, the nickel contact structure may be contacted electrically and silver, nickel, copper and/or tin may be deposited on the nickel contact structure in a plating bath under application of electrical voltage.

Using the method proposed, solar cells may be provided with nickel metal contacts using an industrial printing process, wherein costly silver may be omitted and furthermore, after deposition of a passivation layer, no subsequent high-temperature steps which could jeopardise a passivation effect of the passivation layer need be performed.

According to a third aspect of the present invention, a solar cell is proposed as may be produced inter alia using the production method described above according to the second aspect of the invention. The solar cell has a silicon substrate, on the surface of which is a passivation layer of a dielectric and/or amorphous silicon. Metal contacts based on nickel particles make contact with the surface of the silicon substrate through openings in the passivation layer.

The metal particles forming the metal contacts, for example nickel particles, may lead to a granular structure of the metal contacts. When the paste containing nickel particles as described above is used to create the metal contacts, a partial “baking” of the nickel particles may occur during the sintering step by heating to maximum 600° C., wherein the nickel particles do not melt completely and thus a granular structure remains in the sintered metal contact. Such metal contacts, which may have a granular structure because of the nickel particles used in the printing process during their production, may serve as proof that the printable paste described above or the production method described above with the advantages also described has been used in the production of the solar cells.

The metal contacts may furthermore have nickel silicide at an interface to the silicon substrate. This nickel silicide may lead to a very low contact resistance between the metal contact and the silicon substrate. The nickel silicide may be formed by the direct contact of nickel particles with the silicon substrate surface at high process temperatures. Similarly, if titanium particles are used, a layer of titanium silicide may be formed.

The metal contacts may border or abut to the passivation layer directly at the side. In other words, a surface of the silicon substrate may be covered largely completely with the passivation layer and opened locally only in the region of the metal contacts, so that no exposed surface regions which are neither metallised nor passivated exist adjacent to the metal contacts. This may be achieved for example by the production method described above in which the nickel particles forming the metal contacts are printed locally together with the etching medium, and hence the passivation layer is etched clear exclusively in the region of the metal contacts to be formed.

It is pointed out that features and embodiments of the invention are described here partially in relation to the printable paste, partially in relation to the method for production of a solar cell, and partially in relation to the solar cell itself. A person skilled in the art will however recognise that the corresponding features may be transferred accordingly to the respective other aspects of the invention. In particular the features described may also be combined into sensible combinations, whereby synergy effects may result.

### BRIEF DESCRIPTION OF THE DRAWINGS

The aspects described above and further aspects, features and benefits of the present invention are evident from the description below of specific embodiments with reference to the enclosed drawings, without the invention being restricted thereto.

FIG. 1 shows a section view of a silicon solar cell according to an embodiment of the present invention;

FIG. 2 shows an enlarged extract A of the solar cell shown in FIG. 1;

FIG. 3 shows a flow diagram to illustrate a process sequence for a production method according to an embodiment of the present invention.

The drawings are merely diagrammatical and not to scale. In particular, size ratios, for example between the layers and contact structures, are not necessarily depicted realistically.

### DESCRIPTION OF PREFERRED EMBODIMENTS OF THE INVENTION

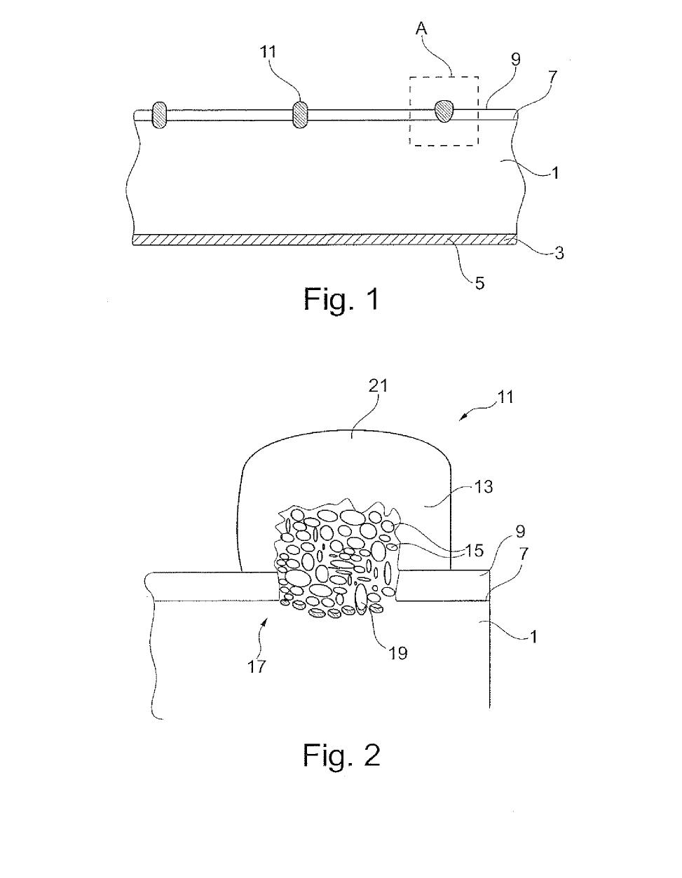

FIGS. 1 and 2 show a simple form of a solar cell according to the invention. A silicon substrate 1 has on its back 3 a full area metal contact 5. Different back contact structures may be produced, such as for example a planar BSF (Back Surface Field) or local contacts with an intermediate dielectric layer as back reflector and/or passivation layer. On the front 7 of the substrate 1, a dielectric layer is deposited as a passivation layer 9. Whereas the substrate 1 has a thickness of e.g. 150 to 300 μm, the passivation layer 9 is only 70 to 90 nm thick. The dielectric layer acts firstly as an anti-reflection layer and secondly serves for passivation of the surface 7. Metal contacts 11 contact the front 7 of the substrate 1 locally with a finger-like structure. The metal contacts 11 locally penetrate through the passivation layer 9 and create a mechanical and electrical contact with the surface 7 of the substrate 1.

As shown in the section view illustrated in FIG. 2, which depicts an enlargement of extract A from FIG. 1, the metal contacts 11 have a special structure. An inner region 13 of a metal contact 11 is composed of a plurality of nickel particles 15. These nickel particles 15 may be sintered together and are in electrically conductive contact with each other. The inner region 13 extends through the passivation layer 9 and makes contact with the front surface 7 of substrate 1. In a contact region 17, the nickel particles 15 here have a layer 19 of nickel silicide at an interface to the silicon substrate 1.

Around the inner region 13, which has a granular structure, is an outer region 21 which is formed from a highly conductive metal such as for example silver, nickel or copper, and has a largely homogenous structure. The outer region 21 here does not penetrate through the dielectric layer 9.

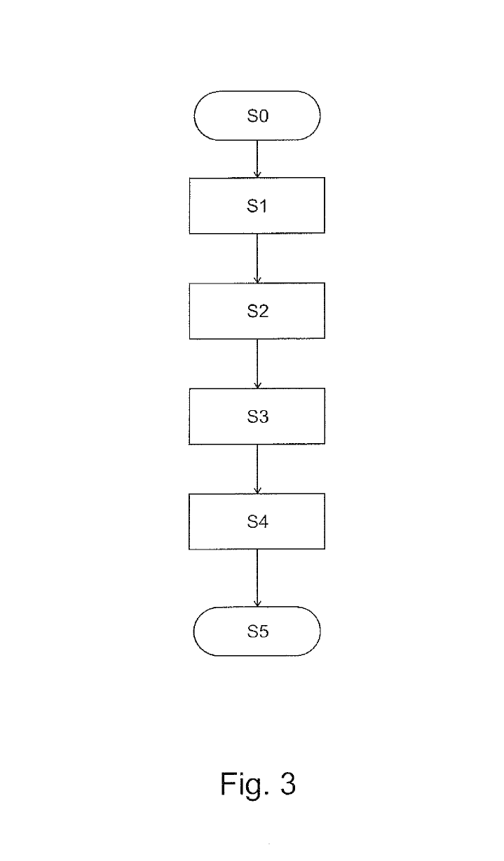

A solar cell according to the invention, as shown as an example in FIGS. 1 and 2, may be produced with a production method according to the invention, as will be explained below with reference to the flow diagram in FIG. 3.

First a silicon substrate 1 is provided (step SO). The silicon substrate 1 may for example be a silicon wafer or a thin silicon layer. The silicon substrate 1 may also be subjected to additional pretreatment steps, such as for example etching steps to eliminate cutting damage or to create a surface texturing, and cleaning steps. Then an emitter may be produced on a surface of the silicon substrate 1, for example by diffusing in suitable doping agents.

Then a passivation layer 9 is deposited on the surface of the silicon substrate 1 prepared in this way (step S1). The passivation layer may for example be a silicon nitride layer deposited by PECVD (Plasma Enhanced Chemical Vapour Deposition). Alternatively an oxide layer may be grown thermally or chemically, or an aluminium oxide layer may be deposited as a passivation layer e.g. using an ALD process (Atomic Layer Deposition), an APCVD process (Atmospheric Pressure Chemical Vapour Deposition) or a PECVD method. As a further alternative, a thin layer of amorphous silicon may be deposited as the passivation layer.

Then a printable paste is applied locally to the previously deposited passivation layer in a screen-printing process (step S2). Alternative printing processes such as for example template printing, roller printing, inkpad printing or a laser transfer process may be used. The printable paste contains both an etching medium based for example on phosphoric acid, and a plurality of nickel particles. The printable paste is for example printed on in the form of narrow, oblong contact fingers with finger widths of 20 to 150 μm and finger heights of 5 to 50 μm.

During a subsequent heating step (step S3), the silicon substrate including the paste printed thereon is heated to a temperature of around 350 to 500° C. and held at this temperature for several seconds. Such a heating step may for example be implemented by passing the silicon substrate through a belt oven. The higher temperature causes an increase in the reactivity of the etching medium contained in the printable paste, so that this etches through the passivation layer 9 within a few seconds. Thus now a direct contact may be achieved between the nickel particles 15 also contained in the paste and the silicon surface 7. A nickel silicide layer 19 is now formed because of the high temperature of over 350° C.

After the heating step, any residual etching medium may be removed from the metal contact structures 11 produced in this way. For example, the substrate 1 may be subjected to a rinsing step in de-ionised water. Alternatively, the quantity of etching medium contained in the paste and the duration and temperature of the heating step may be adapted such that the etching medium evaporates completely during the heating step.

Then in an optional method step (step S4), the nickel contact structure produced in this way may be thickened by plating. Whereas, as shown in FIG. 2, the nickel contact structure produced by the paste is formed with a granular structure and extends through the passivation layer 9 down to the substrate surface 7, the outer plated region 21 has a largely homogenous structure and settles above the granular nickel contact structure and the passivation layer 9.

The formation of the nickel silicide regions 19 allows very low contact resistances between the inner region 13 of the metal contact 11 and the surface of the silicon substrate 1. The plated outer region 21 of the metal contact 11 may ensure very low series resistances along the finger-like contacts. As a whole, this creates the possibility of very low series resistance losses through the metal contacts 11.

To complete the solar cells, further process steps (step S5) may be performed, such as for example the formation of a back contact and edge insulation. These and other supplementary process steps may alternatively also be performed between the process steps S1 to S4 mentioned above.

Finally it is pointed out that the terms “comprise”, “have” etc. do not exclude the presence of further additional elements. The term “a” does not exclude the presence of a plurality of elements or objects. Furthermore in addition to the process steps cited in the claims, further process steps may be necessary or advantageous in order e.g. to produce a definitive solar cell. The reference numerals in the claims serve merely for better legibility and in no way restrict the scope of protection of the claims.

### LIST OF REFERENCE NUMERALS

1 Silicon substrate

3 Back surface

5 Back contact

7 Front surface

9 Passivation layer

11 Metal contact

13 Inner region

15 Nickel particle

17 Contacting region

19 Nickel silicide layer

21 Outer region

1-11. (canceled)

12. Printable medium for etching opening of a passivation layer of at least one of at least one dielectric and amorphous silicon, and for making electrically conductive contact with a silicon substrate adjacent to the passivation layer, wherein the printable medium contains at least:
a medium for chemically etching the passivation layer; and
between 5 w. % and 90 w. % metal particles, wherein the metal particles are at least one of nickel particles and titanium particles,
wherein the printable medium is substantially free from glass frit.

13. Printable medium according to claim 12, wherein the printable medium contains between 5 w. % and 90 w. % of the medium for etching the passivation layer.

14. Printable medium according to claim 12, wherein the metal particles have sizes between 20 nm and 50 μm.

15. Printable medium according to claim 12, wherein the etching medium is adapted to dissolve the passivation layer chemically completely in a region which is covered by the printable medium.

16. Printable medium according to claim 12, wherein the passivation layer contains at least one dielectric selected from a group consisting of silicon nitride, silicon oxide, aluminium oxide, silicon carbide and amorphous silicon.

17. Printable medium according to claim 12, wherein the etching medium contains one or more forms of at least one of phosphoric acid, phosphoric acid salts and phosphoric acid compounds.

18. Printable medium according to claim 12, wherein the etching medium contains at least one of an inorganic mineral acid including hydrochloric acid, phosphoric acid, sulphuric acid, hydrofluoric acid, nitric acid and
an inorganic acid which has an alkyl residue with 1 to 10 C atoms, selected from the group of alkylcarbonic acids, hydroxycarbonic acids and dicarbonic acids, including formic acid, acetic acid, lactic acid and oxalic acid, and
an etching alkaline compound including KOH or NaOH.

19. Method for producing of a solar cell, wherein the method comprises at least the following steps:
providing a silicon substrate;
depositing a passivation layer with at least one of a dielectric and amorphous silicon on a surface of the silicon substrate;
applying a printable medium on the passivation layer, wherein the printable medium contains at least one medium for chemically etching the passivation layer and between 5 w. % and 90 w. % metal particles, wherein the metal particles are at least one of nickel particles and titanium particles, and wherein the printable medium is substantially free from glass frit.

20. Method according to claim 19, furthermore comprising:
heating the printable medium to a temperature between 200° C. and 600° C.

21. Method according to claim 19, furthermore comprising:
heating the printable medium to over 200° C. for a duration of between 1 s and 10 min.

22. Method according to claim 19, furthermore comprising:
thickening of a metal contact structure formed by the applied printable medium, by applying of an additional electrically conductive layer.
